(19) United States
(12) Patent Application Publication
(10) Pub. No.: US 2007/0057152 A1
(43) Pub. Date: Mar. 15, 2007

(54) Image forming apparatus, image processing apparatus, image output apparatus, portable terminal, image processing system, image forming method, image processing method, image output method, image forming program, image processing program, and image output program

(75) Inventor: Toshio Miyazawa, Kanagawa (JP)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Ricoh Company, Ltd.

(21) Appl. No.: 11/518,093

(22) Filed: Sep. 8, 2006

(30) Foreign Application Priority Data
Sep. 9, 2005 (JP) 2005-263033

(51) Int. Cl. H01L 27/00

(52) U.S. Cl. 250/208.1

(57) ABSTRACT

A correction-amount detecting unit detects a correction amount at a time of performing an irreversible correction of an input image. A correction-amount and image integrating unit outputs the correction amount detected by the correction-amount detecting unit and image data of the input image in association with each other.

### PRIORITY

The present application claims priority to and incorporates by reference the entire contents of Japanese priority document, 2005-263033, filed in Japan on Sep. 9, 2005.

### BACKGROUND OF THE INVENTION

1. Field of the Invention

The present invention relates to an image forming apparatus that corrects an input image and outputs the image, an image processing apparatus, an image output apparatus, a portable terminal, an image processing system, an image forming method, an image processing method, an image output method, an image forming program, an image processing program, and an image output program.

2. Description of the Related Art

Conventionally, a technique for detecting an angle of inclination of a scanned image, and correcting the inclination of the image based on the detected inclination angle to output the image has been developed, and is installed in various types of equipment, for preprocessing of document image processing.

For example, Japanese Patent Application Laid-Open No. H03-213053 proposes a technique in which a circumscribed rectangle that includes a black pixel is determined, a reference point, which becomes a reference of inclination detection, is detected from the circumscribed rectangle, and inclination of the image is detected based on the reference point, thereby reducing the processing load in calculating the inclination.

According to an image recognizing apparatus disclosed in Japanese Patent Application Laid-Open No. H09-171538, there is proposed a technique in which an input image is rotated by a predetermined angle, and an inclination angle is detected with respect to the rotated image, thereby increasing detection accuracy when the inclination angle is small.

Thus, various techniques for increasing detection accuracy of an image inclination angle have been developed. However, the possibility of incorrectly detecting the inclination angle cannot be eliminated completely. When the inclination angle is recognized erroneously, the image is corrected with the wrong angle and is output. Therefore, a user who recognizes that the inclination of the image has been corrected incorrectly according to a display of the image or the like needs to perform image processing to correct the inclination again.

However, correction of an inclination angle of a document is generally an irreversible correction that cannot be returned to the state before correction, and by repeating the correction, the image quality degrades. This problem is not limited to the inclination correction of an image, and is a common problem that occurs when an image is output after having been subjected to an irreversible correction.

### SUMMARY OF THE INVENTION

An image forming apparatus, image processing apparatus, image output apparatus, portable, terminal, image processing system, image forming method, image processing method, image output method, image forming program, image processing program, and image output program are described. In one embodiment, an image forming apparatus comprises a correction-amount detecting unit that detects a correction amount at a time of performing an irreversible correction of an input image, and a correction-amount and image integrating unit that outputs the correction amount detected by the correction-amount detecting unit and image data of the input image in association with each other.

### DESCRIPTION OF THE DRAWINGS

FIG. 1 is a block diagram of the configuration of a multifunction product according to a first embodiment of the present invention;

FIG. 2 is an explanatory diagram of an example of a data structure of image data stored in a hard disk drive (HDD);

FIG. 3 is an explanatory diagram of an outline of copy preview processing;

FIG. 4 is a flowchart of an overall flow of the copy preview processing according to the first embodiment;

FIG. 5 is an explanatory diagram of an example of an inclination angle detection process;

FIG. 6A is an explanatory diagram of an example of a correction instruction screen;

FIG. 6B is a flowchart of an overall flow of resolution and compression ratio detection processing according to the first embodiment;

FIG. 6C is an explanatory diagram of an example of a histogram created by a correction amount detector;

FIG. 6D is an explanatory diagram of an example of a data structure of a correction amount setting table;

FIG. 7 is an explanatory diagram of an outline of a fax transmission processing;

FIG. 8 is a flowchart of an overall flow of the fax transmission processing according to the first embodiment;

FIG. 9 is an explanatory diagram of an outline of e-mail transmission processing;

FIG. 10 is a flowchart of an overall flow of the e-mail transmission processing in the first embodiment;

FIG. 11 is an explanatory diagram of an outline of an HDD output processing;

FIG. 12 is a flowchart of an overall flow of the HDD output processing according to the first embodiment;

FIG. 13 is a block diagram of the hardware configuration of the multifunction product;

FIG. 14 is a block diagram of the configuration of an image processing system according to a second embodiment of the present invention;

FIG. 15 is a flowchart of an overall flow of image processing according to the second embodiment;

FIG. 16 is a flowchart of an overall flow of an image output process according to the second embodiment;

FIG. 17 is a block diagram of the configuration of an image processing system according to a third embodiment of the present invention; and

FIG. 18 is a flowchart of an overall flow of an image output process according to the third embodiment.

### DETAILED DESCRIPTION OF THE PREFERRED EMBODIMENTS

Embodiment of the present invention include at least an image output apparatus and method that at least partially solve the problems in the conventional technology.

An image forming apparatus according to one embodiment of the present invention includes a correction-amount detecting unit that detects a correction amount at a time of performing an irreversible correction of an input image; and a correction-amount and image integrating unit that outputs the correction amount detected by the correction-amount detecting unit and image data of the input image in association with each other.

An image output apparatus according to another embodiment of the present invention includes an image-input receiving unit that receives an input of image data that is output in association with a correction amount at a time of performing an irreversible correction of an input image; a correcting unit that corrects the image data received by the image-input receiving unit based on the correction amount; and an output controller that outputs the image data corrected by the correcting unit.

An image processing method according to still another embodiment of the present invention includes detecting a correction amount at a time of performing an irreversible correction of an input image; and outputting the correction amount detected by the correction-amount detecting unit and image data of the input image in association with each other.

The above and other embodiments, features, advantages and technical and industrial significance of this invention will be better understood by reading the following detailed description of presently preferred embodiments of the invention, when considered in connection with the accompanying drawings.

Exemplary embodiments of the present invention will be explained below in detail with reference to the accompanying drawings.

An example in which the present invention is applied to a multifunction product as an image forming apparatus is explained in a first embodiment of the present invention. The multifunction product is an apparatus in which functions of respective devices such as a printer, a copier, a fax, and a scanner are stored in a housing. The image forming apparatus is not limited to the multifunction product, and the present invention can be also applied to any image forming apparatus such as copying machines, fax machines, and scanners.

A multifunction product 100 according to the first embodiment detects an inclination angle of a scanned image (input image) and outputs the detected inclination angle in association with the input image. Four output methods are explained. That is, a method of printing the image after preview display of the image on a display unit, a method of faxing the image after preview display of the image on the display unit, a method of transmitting the image to an external apparatus by an e-mail, and a method of outputting the image to a built-in storing unit.

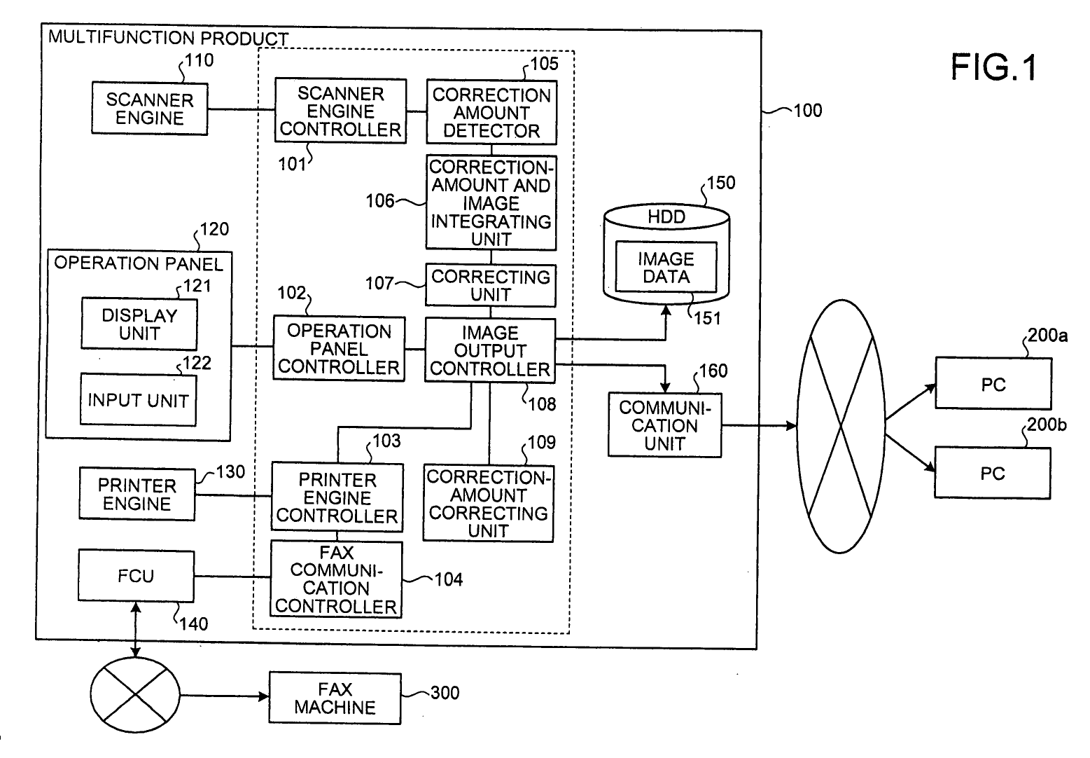

FIG. 1 is a block diagram of the configuration of the multifunction product 100 according to the first embodiment. As shown in FIG. 1, the multifunction product 100 includes, as major hardware, a scanner engine 110, an operation panel 120 as a user interface, a printer engine 130, a fax control unit (FCU) 140, an HDD 150, and a communication unit 160.

The multifunction product 100 also includes, as a major software configuration, a scanner engine controller 101, an operation panel controller 102, a printer engine controller 103, a fax communication controller 104, a correction amount detector 105, a correction-amount and image integrating unit 106, a correcting unit 107, an image output controller 108, and a correction-amount correcting unit 109.

The operation panel controller 102 corresponds to a display controller in the present invention. The printer engine controller 103, the fax communication controller 104, and the image output controller 108 correspond to an output controller in the present invention.

The scanner engine 110 scans a document by driving a scanner.

The operation panel 120 includes a display unit 121 that displays function setting keys, number of copies, and a message describing the state of the multifunction product 100, and an input unit 122 that receives key input by a ten key, a clear/stop key, a start key, a warm-up key, a reset key, an initialize key, a print key, a transmit key, and a save key. The display unit 121 also serves as an input unit that can be operated by a touch panel input method, as well as displaying an image. The display unit 121 of the operation panel 120 corresponds to the display unit in the present invention.

The printer engine 130 executes printing of image data on a paper medium. The FCU 140 controls fax transmission of image data to an external fax machine 300.

The HDD 150 stores image data 151 of an input image in association with a correction amount. The storing unit is not limited to the HDD, and any generally used storing units, such as optical disks and memory cards can be used. The HDD 150 corresponds to a storing unit in the present invention.

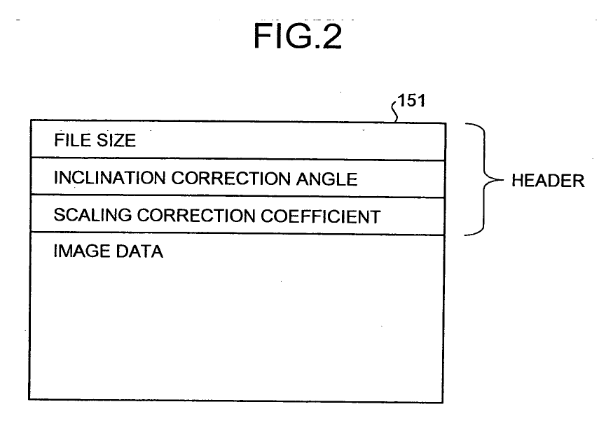

FIG. 2 is an explanatory diagram of an example of a data structure of the image data 151 stored in the HDD 150. As shown in FIG. 2, the image data 151 is added with a header including a file size, an inclination correction angle, and a correction amount, which is a variable at the time of executing correction, expressed by a scaling correction coefficient, and is stored in the HDD 150.

FIG. 2 is an example of the image data 151 in a portable document format (PDF) file format. In the PDF file format, information for executing an affine transformation for rotating and scaling an image at the time of displaying the image can be defined in the header. The inclination correction angle in FIG. 2 denotes a variable required for rotation in the affine transformation, and the scaling correction coefficient in FIG. 2 denotes a variable required for scaling in the affine transformation.

The correction amount to be stored in the header is not limited to the one for inclination correction, and any correction amount of, for example, resolution and compression ratio can be stored, provided that it is a variable to be used at the time of correcting the image. Further, the file format is not limited to the PDF file, and any file format such as an exchangeable image file format (Exif), an extensible markup language (XML) format, and tagged image file format (Tiff) can be used, provided that the image data can be stored in association with a correction amount for correction. Further, the image data and the correction amount can be stored in separate files.

Referring back to FIG. 1, the communication unit 160 transmits the image data to an external apparatus such as a personal computer (PC) 200a and a PC 200b via a network such as the Internet.

The scanner engine controller 101 controls the scanner engine 10.

The operation panel controller 102 controls display of various screens on the display unit 121 of the operation panel 120, and receives a key input event from the input unit 122.

The operation panel controller 102 outputs the image data corrected according to the correction amount to the display unit 121. As a result, a user can confirm the image after correction by preview display. That is, when the image after correction is wrong due to erroneous recognition or erroneous detection of the correction amount, the user can confirm the erroneous recognition by confirming the image, and can re-execute for appropriate correction.

The printer engine controller 103 controls the printer engine 130. The fax communication controller 104 controls the FCU 140.

The correction amount detector 105 detects an inclination angle from the image data of the image input from the scanner. In the inclination detection, any conventional method such as the inclination detection method described in Japanese Patent Application Laid-Open No. H03-213053 and Japanese Patent Application Laid-Open No.H09-171538 can be used.

The input source of the image data is not limited to the scanner, and the image can be input from any generally used image input devices such as a digital camera. An image input by the image input device and stored in a storage device such as the HDD 150 can be input as well.

The correction-amount and image integrating unit 106 integrates the inclination angle detected by the correction amount detector 105 and the image data of the input image, and outputs the image data. For example, the correction-amount and image integrating unit 106 outputs the image data in the PDF file format, and sets the inclination angle detected by the correction amount detector 105 in an “inclination correction angle” portion of the header in the PDF file.

In the first embodiment, while the inclination angle itself detected by the correction amount detector 105 is set in the inclination correction angle portion, the inclination correction angle, which is an angle necessary for correction, can be set therein. This is because when it is assumed that the inclination correction angle is beta (β), a relation of β=(-alpha(α)) is generally established between the inclination correction angle and the inclination angle α. When it is detected that a document is inclined by α degrees, one correction by −α degrees is only required.

The correcting unit 107 corrects the image data according to the correction amount set in the header and outputs the image. For example, when the inclination correction angle is set in the header, the correcting unit 107 performs an inclination correction process for rotating the image data by the inclination correction angle, and outputs the image data as a result of the process. Any generally used methods such as the affine transformation can be applied to the inclination correction process.

When the correction amount is for resolution, the correcting unit 107 executes scaling for changing the resolution. Any generally used methods such as a method of changing the resolution by an interpolation of pixels can be used for scaling.

When the correction amount is for a compression ratio, the correcting unit 107 performs an image compression process for compressing the image data according to the compression ratio. Any generally used methods such as a run length method, a Huffman method, and an LZ77 method can be used for the image compression process.

The image output controller 108 controls an output of image data output by the correction-amount and image integrating unit 106 or image data corrected by the correcting unit 107 according to an output destination of the image data. For example, when a preview image is to be displayed on the display unit 121 of the operation panel 120, the image output controller 108 controls so that the image data corrected based on the correction amount and output by the correcting unit 107 is output to the operation panel controller 102.

For example, when an image is output by the printer or is transmitted from the fax machine, the image output controller 108 controls so that the corrected image data is output to the printer engine controller 103 or the fax communication controller 104.

When an image is output to the built-in storage unit or transmitted to the external apparatus by an e-mail, the image output controller 108 controls so that the image data output by the correction-amount and image integrating unit 106 is output to the HDD 150 or the communication unit 160. The image data output by the correction-amount and image integrating unit 106 is not the corrected image data, but includes the input image data. Therefore, since the external apparatus can correct the image based on the input image, degradation of image quality can be minimized.

The image output controller 108 can be also configured to output the image data corrected by the correcting unit 107 to the HDD 150 or the communication unit 160. In this case, if an image corrected based on the correction amount, which is confirmed to be correct by preview display or which is appropriately corrected by the correction-amount correcting unit 109, is output, image data corrected based on an erroneously recognized correction amount will not be output.

The correction-amount correcting unit 109 corrects the correction amount associated with the image data, and outputs the image data in association with the correction amount after correction. The correction-amount correcting unit 109 can be configured so that the user can directly correct the correction amount associated with the image data. Further, the correction-amount correcting unit 109 can be configured to detect a correct inclination angle specified by the user on the image displayed on the display unit 121 or the like, and rewrite the inclination angle associated with the image data.

An image forming processing performed by the multifunction product 100 according to the first embodiment is explained below. A copy preview processing that forms, displays on the display unit 121 and then prints a preview, is explained.

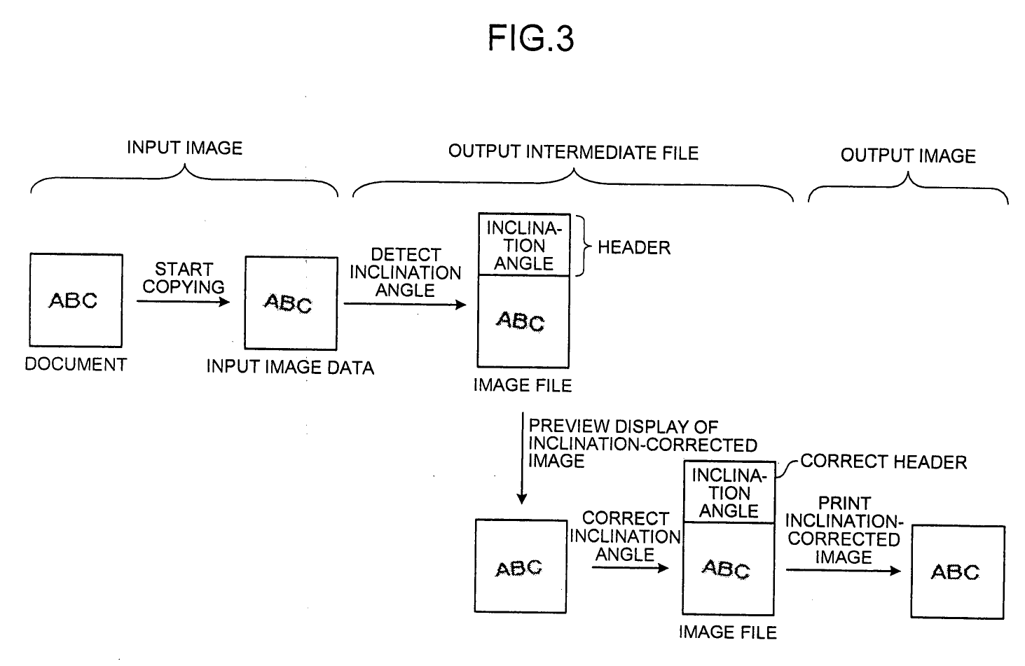

FIG. 3 is an explanatory diagram of an outline of the copy preview processing. As shown in FIG. 3, the copy preview processing is divided into three steps of an image input process, an intermediate file output process, and an image output process.

In the image input process, a document is scanned by the scanner engine according to copy start operation, and the input image data is output.

In the intermediate file output process, the inclination angle is detected from the input image data, and the image data in which the detected inclination angle is set in the header of the input image data is output as an intermediate file. When an image corrected based on the detected inclination angle is preview displayed on the display unit 121 and the detected inclination angle is wrong, the header is updated based on the inclination angle corrected by the correction-amount correcting unit 109 according to an angle specified by the user.

In the image output process, the image is printed, with the inclination being corrected according to the inclination angle stored in the header. When it is determined that the detected inclination angle is right, an image corrected according to the initially detected inclination angle is printed.

Thus, instead of directly printing the image corrected based on the detected inclination angle, it is determined whether the detected inclination angle is right by the preview display, and after the inclination angle is corrected, the image is printed. Accordingly, a correct image can be output with erroneous recognition of the inclination angle being removed.

According to the conventional method, when it is found that the detected inclination angle is wrong by the preview, and correction is to be performed again, the inclination-corrected image needs to be corrected again. This is because only the inclination-corrected image data is output, and the image data of the input image, which is an image before the correction, does not remain. Generally, since inclination correction of an image is an irreversible correction such that the image data before the correction cannot be restored, the image data before the correction cannot be restored from the image data after the correction. Accordingly, there is a possibility that the image quality degrades due to repetitive correction.

On the other hand, according to the method in the first embodiment, not the image data of the image after the correction but the image data of the input image is output as an intermediate file. Therefore, even when the inclination of the image needs to be corrected again, degradition of image quality due to repetitive correction can be avoided.

The correction amount is not limited to the inclination angle, and any variables can be handled as the correction amount, provided that the variables are for performing appropriate image processing corresponding to the content of the input image data.

For example, the present invention is also applicable to an example in which an appropriate resolution is detected according to a font size of characters included in image data, and an image is output with the detected resolution. In this case, the resolution of the image is handled as the correction amount.

Specifically, for example, image data is output with a resolution of 400 dots per inch (DPI) the same as that at the time of reading, with respect to an input image including a normal document with many characters of small font size. On the other hand, with respect to an input image including a document or the like for presentation including many characters of large font size, the image data is corrected to a low resolution image of 200 DPI and output.

Generally, correction from a high resolution image to a low resolution image is an irreversible correction. Therefore, if the font size is wrongly determined, and a low resolution image is corrected again to a high resolution image, after performing correction to a low resolution image with respect to an image to be output with high resolution, the image quality degrades.

Even in this case, by applying the present invention, since the high resolution image before the correction is stored, image processing can be performed again with an appropriate correction amount, without degrading the image quality.

Alternatively, the present invention can be applied to an example in which compression ratio at the time of outputting, for example, a joint photographic experts group (JPEG) format file is detected, and image data is output with the detected compression ratio. In this case, the compression ratio of the image is handled as the correction amount.

Specifically, for example, while image data can be output with a high compression ratio with respect to an input image including many pictures, image data can be output with a low compression ratio with respect to an input image including many characters.

In compressing the JPEG format, an irreversible compression method where a data loss occurs in order to increase the compression ratio can be adopted. In this case, an input image before the compression cannot be restored from the compressed image. Therefore, if data type of an image is determined incorrectly, and a correction to an image of low compression ratio is to be performed again after the image including many characters to be output at low compression ratio is output at high compression ratio, the image quality degrades.

Even in this case, by applying the present invention since the input image before the correction is stored, image processing can be performed again with an appropriate correction amount, without degrading the image quality.

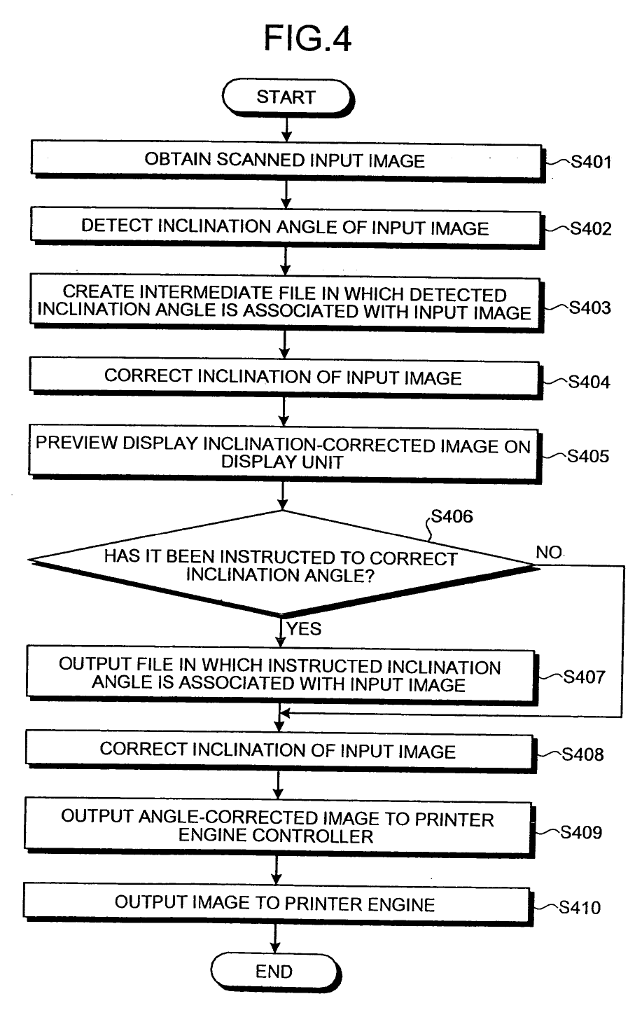

Details of the copy preview processing by the multifunction product 100 according to the thus configured first embodiment are explained next. FIG. 4 is a flowchart of an overall flow of the copy preview processing in the first embodiment.

The scanner engine controller 101 obtains a scanned input image (step S401). The correction amount detector 105 detects an inclination angle of the input image (step S402).

Specifically, the inclination angle is detected as described below. For example, when an image input to the correction amount detector 105 is compressed according to the JPEG format, the image is expanded and developed as a bitmap image. An inclination of the input image developed to the bitmap image is detected according to the method described in Japanese Patent Application Laid-Open No. H03-213053 or Japanese Patent Application Laid-Open No. H09-171538, or by extracting a straight line from the image.

In the method of extracting a straight line, a method of using Hough transform is well known. When an input image is a multi-level image such as a color or gray image, a method of performing binarization processing to obtain black connected components, and extracting character lines by using a coordinate of the black connected components, to detect an inclination angle from inclination of the character lines can be used.

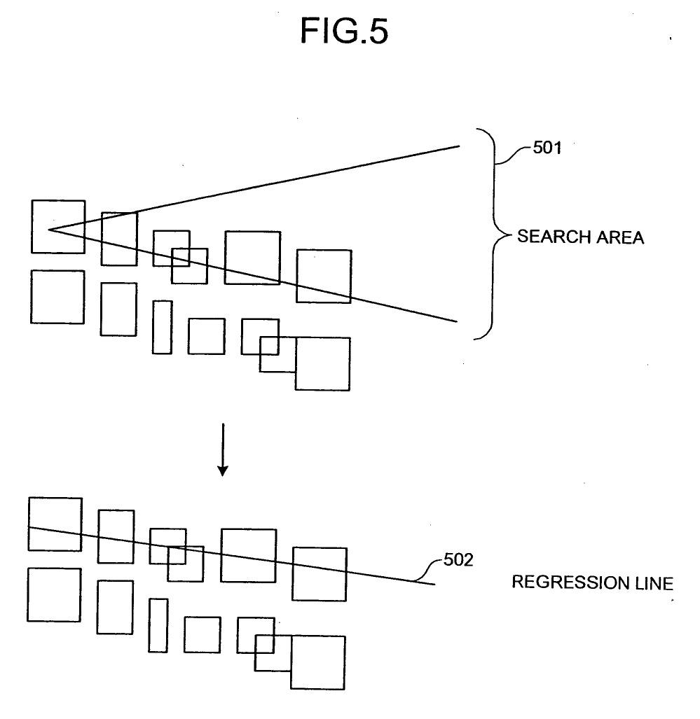

FIG. 5 is an explanatory diagram of an example of an inclination angle detection process, in which an inclination angle is detected from inclination of a character line.

In FIG. 5, portions indicated by rectangles denote the black connected components. A character line can be extracted by determining a central coordinate of the respective black connected components and determining a regression line 502 of the central coordinate included in a predetermined search area 501, thereby detecting inclination of the character line.

In other words, when it is assumed that the regression line 502 is expressed by Y=aX+b, “a” denotes the inclination of the line, and an inclination angle (α) of the regression line can be calculated from “a”.

After the correction amount detector 1 05 detects an inclination angle of an input image at step S402, the correction-amount and image integrating unit 106 creates an intermediate file in which the detected inclination angle is associated with the input image (step S403).

Specifically, the correction-amount and image integrating unit 106 creates the intermediate file, in which the detected inclination angle is set in the header of the image data of the input image, and outputs the file. For example, when the intermediate file is output in a PDF file format, the value of the detected inclination angle is set to the inclination correction angle stored in the header as shown in FIG. 2.

Not only the image data of the input image but also the image data of the corrected image can be stored simultaneously. When only the image data of the input image is stored, since the inclination correction process needs to be performed at the time of display, a processing load on the display apparatus side is increased. By simultaneously storing the image data after correction, the processing load on the display apparatus side can be reduced.

The correcting unit 107 then executes the image inclination correction process based on the inclination angle, which is the correction amount stored in the header of the intermediate file, and the image data in the intermediate file (step S404).

Specifically, the inclination of an image is corrected in the following manner. Generally, the inclination is corrected by a method referred to as affine transformation. The affine transformation can be expressed as follows, assuming that a pixel of an original image is (X0, Y0), a pixel after inclination correction is (X1, Y1), and the inclination angle is α.
X0=cos(α)X1+sin(α)Y1
Y0=−sin(α)X1+cos(α)Y1
(X1, Y1) is changed from (0, 0) to (n, m) (n: number of pixels in an X direction, m: number of pixels in a Y direction) and substituted in the above equation, to calculate the value of (X0, Y0) for each pixel. By repeating this, it can be determined which pixel value of the original image is mapped as the corrected pixel.

The value of (X0, Y0) is not necessarily an integer, and in many cases, becomes a real number including a decimal point. In this case, a pixel value close to the original image can be assigned by rounding off. Alternatively, a close pixel value can be weighted according to an actual value to determine an approximate value. For example, when the real number is 4.4, an approximate value is calculated by calculating the fourth and the fifth close pixels at a weight of 4:6, and this is designated as the corrected pixel value.

Since there is a case that the pixel value after rotation is calculated by using the approximate value, in general, the pixel value of the original image cannot be reproduced from the rotated image. In other words, inclination correction of an image is an irreversible correction.

After the correcting unit 107 corrects the inclination of an image at step S404, the operation panel controller 102 preview displays the inclination-corrected image on the display unit 121 (step S405).

The operation panel controller 102 then determines whether the user has instructed correction of the inclination angle (step S406).

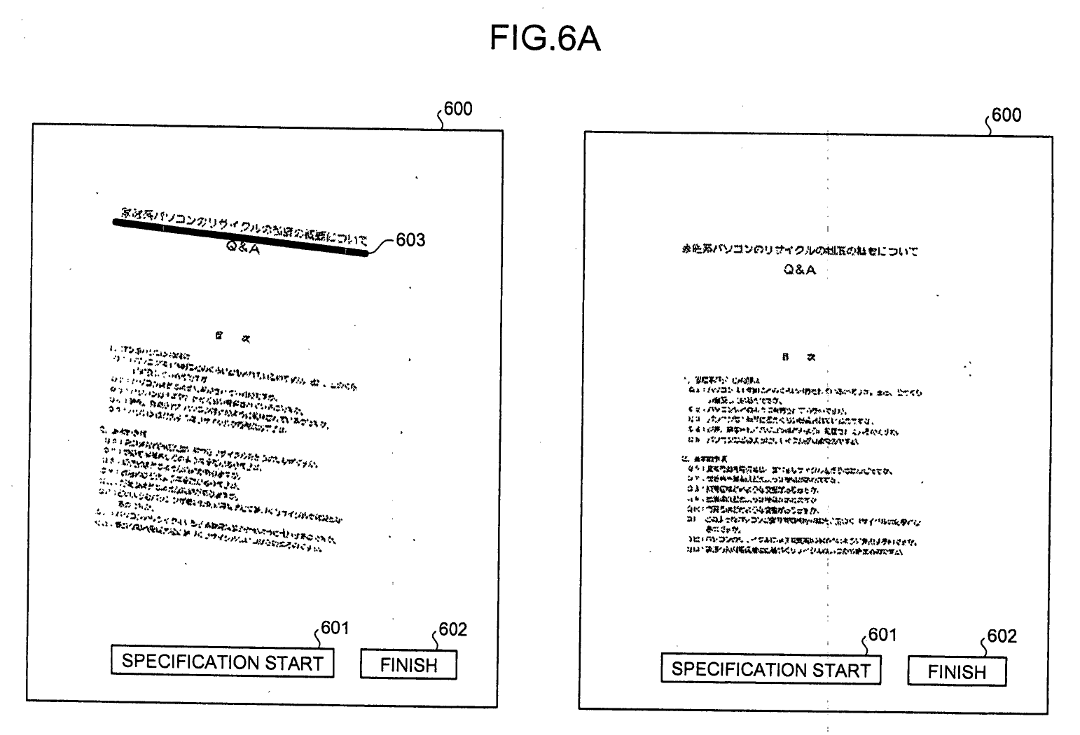

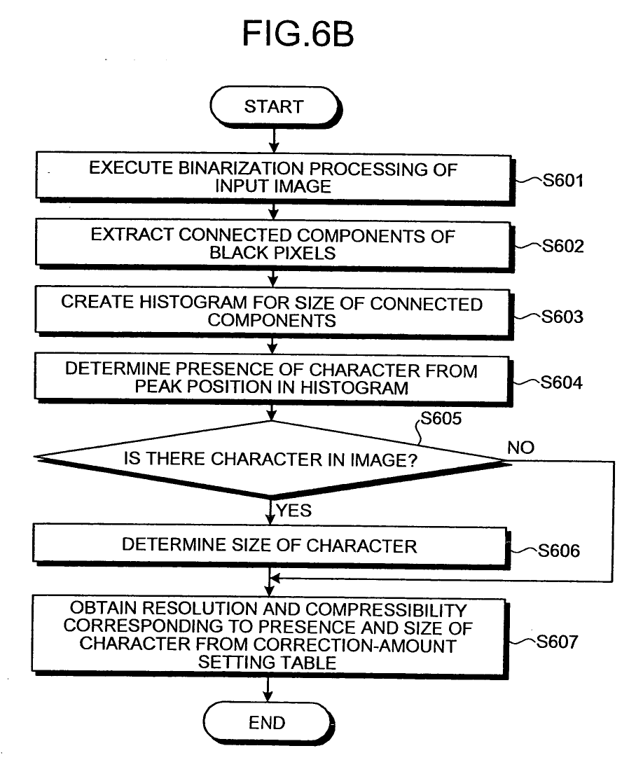

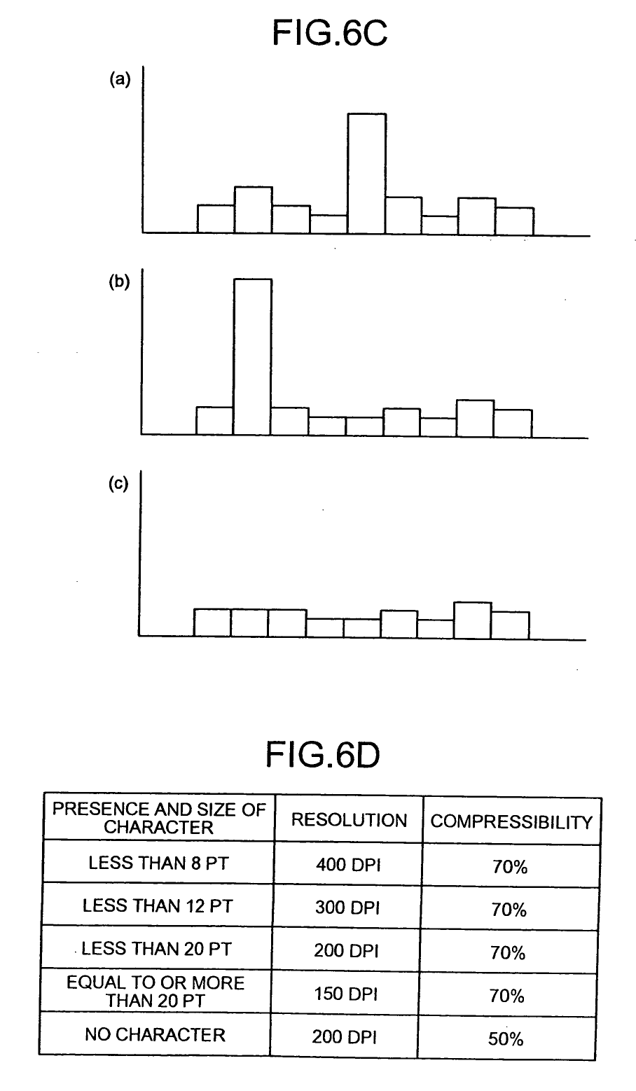

FIG. 6A is an explanatory diagram of an example of a correction instruction screen. As shown in FIG. 6A, a correction instruction screen 600 displays an image whose inclination is corrected by the correcting unit 107 in the middle of the screen. A specification start button 601 for the user to start specifying an angle, and a finish button 602 for completing angle specification are displayed at the lower part of the screen.

When the inclination angle is to be corrected, the user presses the specification start button 601, draws a straight line 603 to a portion that should be displayed horizontally on the displayed preview screen, and presses the finish button 602. Accordingly, the operation panel controller 102 can determine that the user has instructed correction of the inclination angle. The correction instruction screen can be also configured such that the correction angle is specified by providing a column for inputting a numerical value of the correction angle.

When the operation panel controller 102 determines that the user has instructed correction of the inclination angle at step S406 (step S406: Yes), the correction-amount correcting unit 109 outputs a file of the image data in which the instructed inclination angle is associated with the input image (step S407).

For example, when the user specifies the inclination angle by specifying a straight line, the correction-amount correcting unit 109 detects the inclination angle of the specified straight line, replaces the inclination angle stored in the header of the image data of the input image by the detected angle, and outputs the image data.

When the user corrects the inclination angle by directly specifying a value of the correction angle, the correction-amount correcting unit 109 replaces the inclination angle stored in the header of the image data of the input image by the specified angle, and outputs the image data.

After the correction-amount correcting unit 109 outputs the file of the image data, or when the operation panel controller 102 determines that the user has not instructed a correction of the inclination angle at step s406 (step S406: No), the correcting unit 107 executes the inclination correction process of the image based on the inclination angle stored in the header of the file and the image data in the file (step S408). The inclination correction process of the image is executed by the same method as at step S404.

The image output controller 108 outputs the inclination-corrected image to the printer engine controller 103 (step S409).

Lastly, the printer engine controller 103 outputs the image to the printer engine 130 to finish the copy preview processing (step S410).

While an example in which the inclination angle of the input image is detected at step S402 has been explained, the detection of the correction amount with respect to the input image is not limited to the inclination angle. Details of the detection process when appropriate resolution and compression ratio at the time of outputting the input image are detected are explained.

FIG. 6B is a flowchart of an overall flow of a resolution and compression ratio detection processing in the first embodiment.

The correction amount detector 105 binarizes processing of the input image (step S601), to extract connected components of black pixels (step S602). The extracted connected components of the black pixels are expressed, for example, in the same form as rectangles shown in FIG. 5.

The correction amount detector 105 then creates a histogram for the size of the connected components of the black pixels (step S603). FIG. 6C is an explanatory diagram of an example of the histogram created by the correction amount detector 105.

In FIG. 6C, an example of the histogram is shown in which the size (number of pixels) of the connected components of the black pixels is plotted on an X axis, and the frequency is plotted on a Y axis. A graph (a) shown in FIG. 6C is an example of the histogram with respect to an image including a character therein. Graphs (b) and (c) shown in FIG. 6C are examples of the histogram with respect to images not including any character therein.

After having created the histogram at step S603, the correction amount detector 105 determines the presence of a character based on a peak position of the histogram (step S604). Specifically, if there is a peak in a predetermined area calculated based on the size of characters of from about 8 points (PT) to 12 PT frequently included in general office documents and the scanned image resolution, the correction amount detector 105 determines that there is a character.

On the other hand, when there is a peak position, and the sizes (=X axis) of the connected components of the black pixels have a peak near zero, the image can be considered to be a dot photographic image, and hence the correction amount detector 105 determines that there is no character. When there is no peak position, the correction amount detector 105 also determines that there is no character.

For example, when there is a peak position in the connected components of a medium size as in the histogram shown in (a) of FIG. 6C, the correction amount detector 105 determines that there is a character in the image. When there is a peak position near zero on the X axis as shown in (b) of FIG. 6C, or there is no peak position as shown in (c) of FIG. 6C, the correction amount detector 105 determines that there is no character in the image.

The correction amount detector 105 determines whether there is a character in the image (step S605). When there is a character (step S605: Yes), the correction amount detector 105 determines the size of the character (step S606). Specifically, the correction amount detector 105 determines the size of the character by determining in which area the peak position is present, in a predetermined area of the peak position, where it is determined that there is a character.

After determining the size of the character, or when it is determined that there is no character at step S605 (step S605: No), the correction amount detector 105 refers to a correction amount setting table stored in a storing unit such as the HDD 150 to obtain resolution and compression ratio corresponding to the presence of a character and the size of the character (step S607).

FIG. 6D is an explanatory diagram of an example of a data structure of the correction amount setting table. As shown in FIG. 6D, the correction amount setting table stores presence and the size of a character, resolution, and compression ratio in association with one another.

The correction amount detector 105 obtains the corresponding resolution and compression ratio from the correction amount setting table by using the presence of a character detected at step S604 and the size of the character detected at step S606 as search keys. For example, when there is a character, and the size of the character is determined to be less than 8 PT, since many small characters are included, the correction amount is detected in order to increase the resolution (400 DPI) and the compression ratio (70%).

At the time of obtaining the resolution and the compression ratio from the presence of a character and the size of the character, a calculation can be performed according to a predetermined calculating formula.

The intermediate file creation process, the preview process, and the like can be executed by using the detected resolution and compression ratio as the correction amount as in the case of using the inclination angle as the correction amount.

A fax transmission processing is explained next, which is an example of transmitting a formed image by fax, after the formed image is preview displayed on the display unit 121.

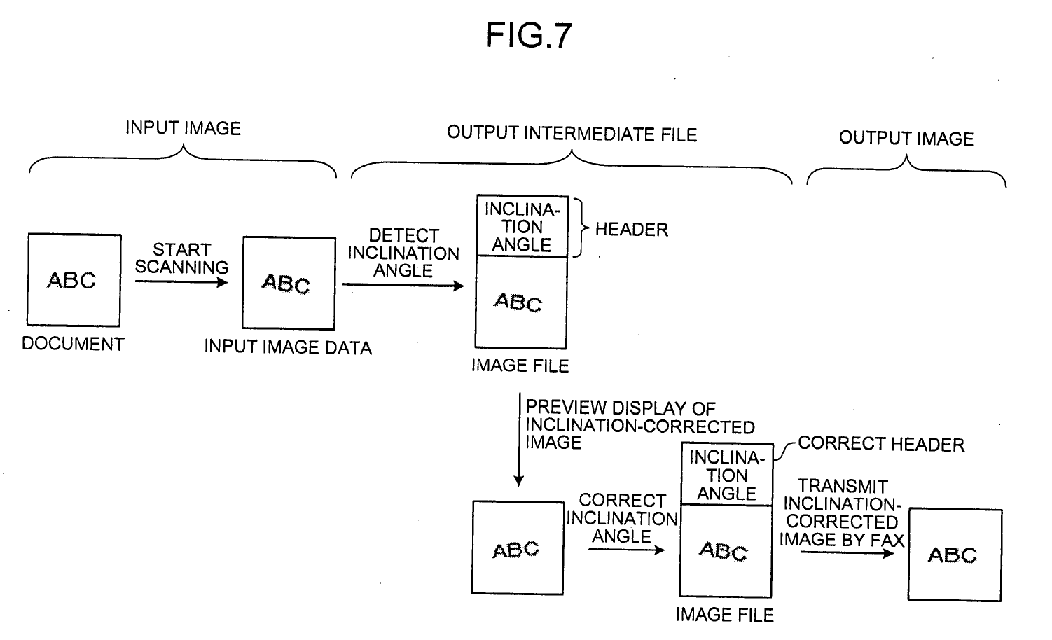

FIG. 7 is an explanatory diagram of an outline of the fax transmission processing. The fax transmission processing is divided into three steps of an image input process, an intermediate file output process, and an image output process, as in the copy preview processing shown in FIG. 3.

The fax transmission processing is different from the copy preview processing in that instead of printing the inclination-corrected image, it is faxed in the image output process. The image input process and the intermediate file output process are the same as those in the copy preview processing, and hence explanation thereof is omitted.

In the image output process, the image corrected according to the inclination angle stored in the header is faxed to the external fax machine 300. When it is determined that the detected inclination angle is right, the image corrected according to the initially detected inclination angle is faxed.

Thus, instead of directly printing the image corrected based on the detected inclination angle, it is determined whether the detected inclination angle is right by the preview display, and after the inclination angle is corrected as required, the image is faxed. Accordingly, a correct image can be output with erroneous inclination recognition being dissolved.

Since even after the inclination angle has been corrected, the inclination can be corrected again based on the image data of the input image stored as the intermediate file to output the image, the degradation of image quality due to repetitive correction can be avoided.

While an example of fax transmission has been explained, the present invention is also applicable to an example of receiving a fax. In other words, the inclination of an image is confirmed on the preview screen at the time of reception, the detected inclination angle is corrected as required, and then the inclination correction process of the image according to the inclination angle can be performed to print the image data.

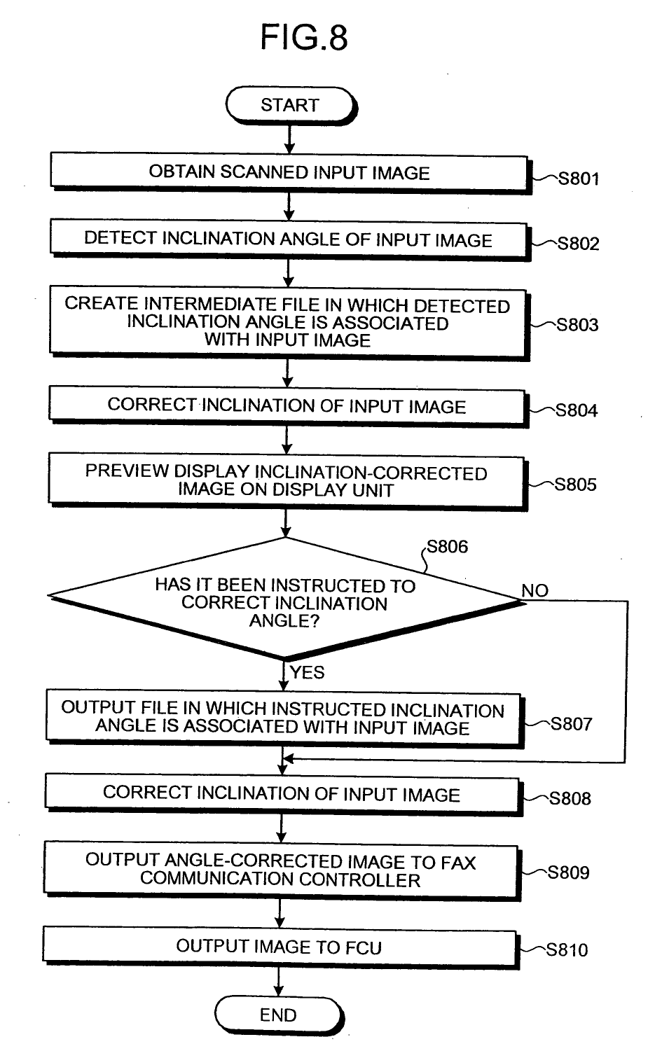

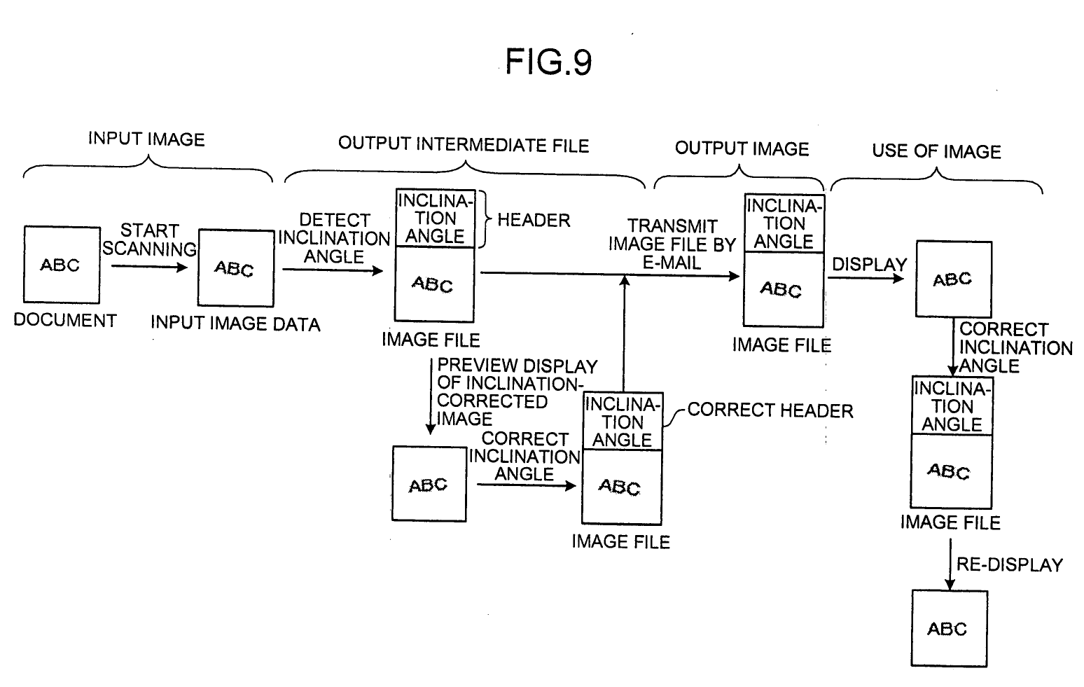

Details of the fax transmission processing performed by the multifunction product 100 according to the first embodiment are explained below. FIG. 8 is a flowchart of an overall flow of the fax transmission processing in the first embodiment.

The preview process and the input image correction process at steps S801 to S808 are the same as those at steps S401 to S408 in the copy preview processing shown in FIG. 4, and hence explanation thereof is omitted.

After the correcting unit 107 executes the inclination correction process of the image at step S808, the image output controller 108 outputs the inclination-corrected image to the fax communication controller 104 (step S809). The fax communication controller 104 outputs the image to the FCU 140 to finish the fax transmission processing (step S810).

E-mail transmission processing, which is an example in which a formed image is transmitted to the external apparatus by e-mail is explained.

FIG. 9 is an explanatory diagram of an outline of the e-mail transmission processing. As shown in FIG. 9, the e-mail transmission processing is divided into four steps of the image input process, the intermediate file output process, the image output process, and use of the image.

The e-mail transmission processing is different from the copy preview processing or the fax transmission processing in that in the image output process, the inclination-corrected image is not printed or faxed, but the file itself of the image data is output without performing inclination correction. The image input process and the intermediate file output process are the same as those in the copy preview processing or the fax transmission processing, and hence explanation thereof is omitted.

In the image output process, the file of the image data in which the inclination angle is stored in the header is transmitted to an external apparatus such as a PC by e-mail.

At the step of using the image, the external apparatus having received the e-mail can freely use the image data. For example, the inclination of the image data can be corrected based on the inclination angle stored in the header, and displayed on the screen. When the inclination angle is wrong, the inclination angle can be corrected on the external apparatus, and inclination correction of the image can be re-executed based on the corrected value of the inclination angle to output the image. At this time, since the correction can be executed based on the received image data of the input image, the degradation of image quality due to repetitive correction can be avoided.

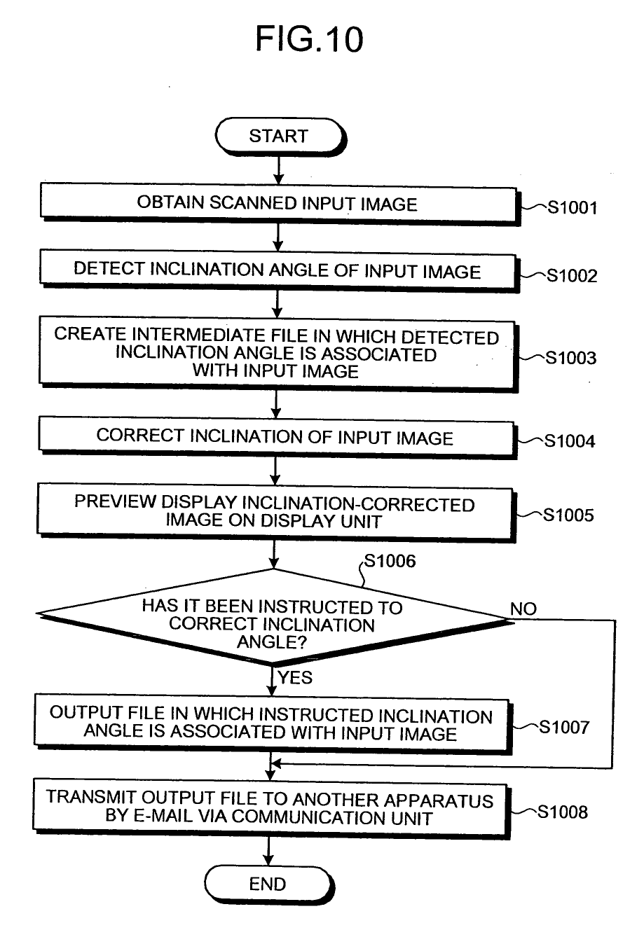

Details of the e-mail transmission processing performed by the multifunction product 100 according to the first embodiment are explained next. FIG. 10 is a flowchart of an overall flow of the e-mail transmission processing in the first embodiment.

Since the preview process and the inclination angle correction process at steps S1001 to S1007 are the same as those at steps S401 to S407 in the copy preview processing shown in FIG. 4, explanation thereof is omitted.

After the correction-amount correcting unit 109 outputs a file of image data (step S1007), or when the operation panel controller 102 determines that the user has not instructed correction of inclination angle (step S1006: No), the image output controller 108 transmits the file of the image data output via the communication unit 160 to another apparatus by e-mail (step S1008), to finish the e-mail transmission processing.

In the e-mail transmission processing, since the external apparatus can display the angle-corrected image and correct the inclination angle and the like, the preview display (steps S1004 to S1007) in the intermediate file output process can be omitted.

An HDD output processing, which is an example of outputting the formed image to the built-in HDD 150, is explained next.

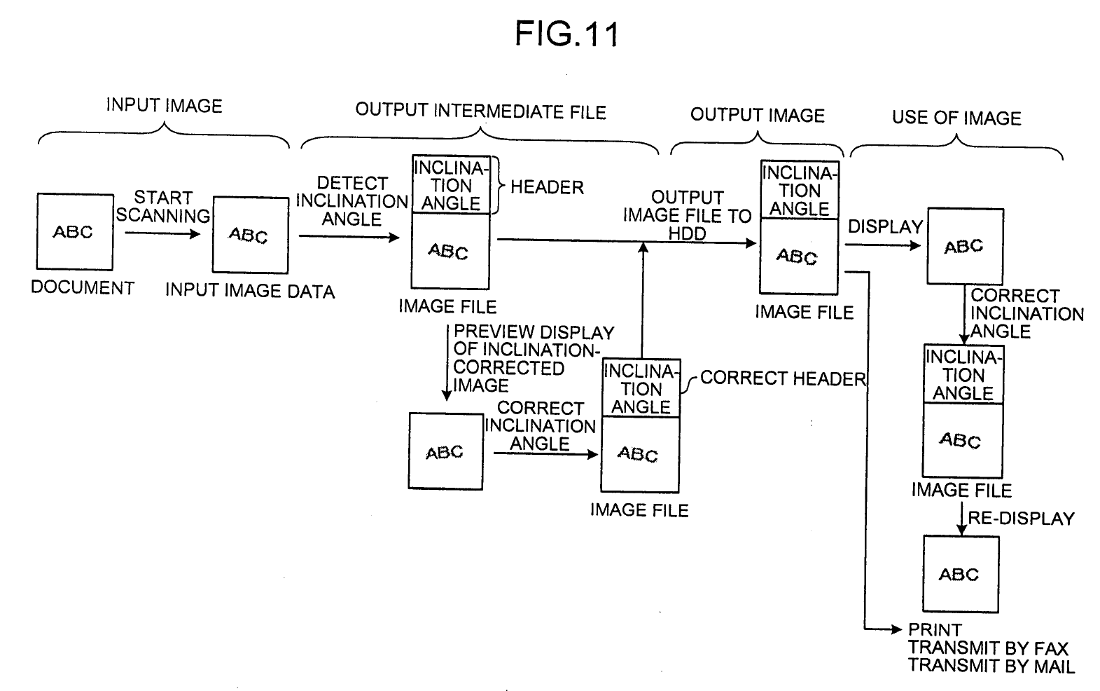

FIG. 11 is an explanatory diagram of an outline of the HDD output processing. As shown in FIG. 11, the HDD output processing is divided into four steps of the image input process, the intermediate file output process, the image output process, and use of the image.

The HDD output processing is different from that of the e-mail transmission processing in that in the image output process, the image file is not transmitted to the external apparatus by e-mail, but the image file is output to the HDD 150, which is a built-in storage unit. Since the image input process and the intermediate file output process are the same as those in the copy preview processing, the fax transmission processing, and the e-mail transmission processing, explanation thereof is omitted.

In the image output process, the file of the image data, in which the inclination angle is stored in the header, is output to the built-in HDD 150.

At the step of using the image, for example, the inclination angle can be corrected by re-displaying the image on the display unit 121 of the multifunction product 100. Further, the image can be printed, faxed, or transmitted by e-mail based on the image data stored in the HDD 150.

At this time, since the correction can be executed based on the received image data of the input image, the degradation of image quality due to repetitive correction can be avoided.

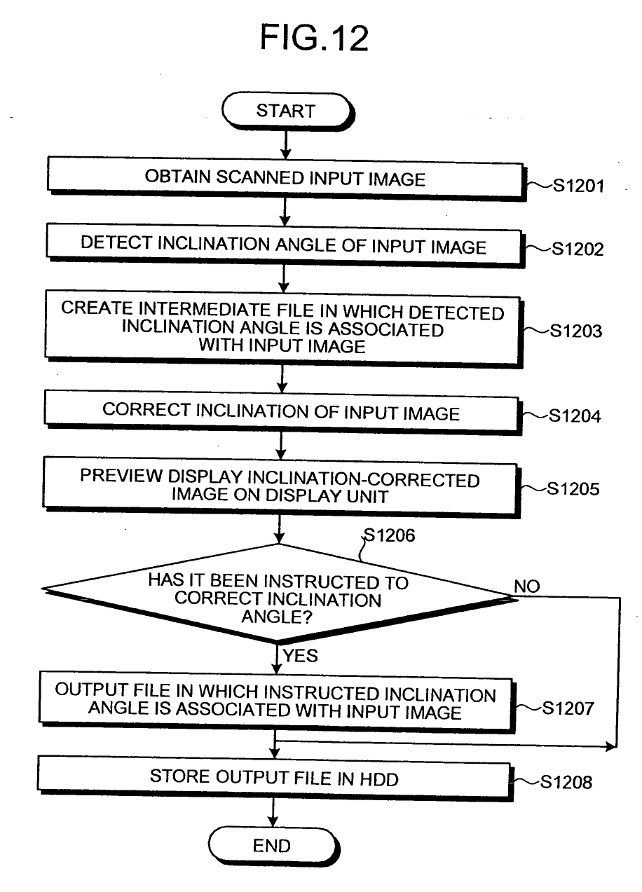

Details of the HDD output processing performed by the multifunction product 100 according to the first embodiment is explained next. FIG. 12 is a flowchart of an overall flow of the HDD output processing in the first embodiment.

Since the preview process and the inclination angle correction process at steps S1201 to S1207 are the same as those at steps S1001 to S1007 in the e-mail transmission processing shown in FIG. 10, explanation thereof is omitted.

After the correction-amount correcting unit 109 outputs a file of image data (step S1207), or when the operation panel controller 102 determines that the user has not instructed correction of inclination angle (step S1206: No), the image output controller 108 stores the output image data in the HDD 150 (step S1208), to finish the HDD output processing.

Similarly to the e-mail transmission processing, the preview display in the intermediate file output process (steps S1204 to S1207) can be omitted in the HDD output processing.

Thus, in any of the four image data output methods, the inclination angle as the correction amount and the image data of the input image are associated with each other and stored as an intermediate file. Therefore, when the inclination-corrected image needs to be corrected again due to erroneous recognition of the inclination angle, a correction can be performed not based on the inclination-corrected image, but based on the image data of the input image. Accordingly, degradation of image quality due to repetitive correction can be avoided.

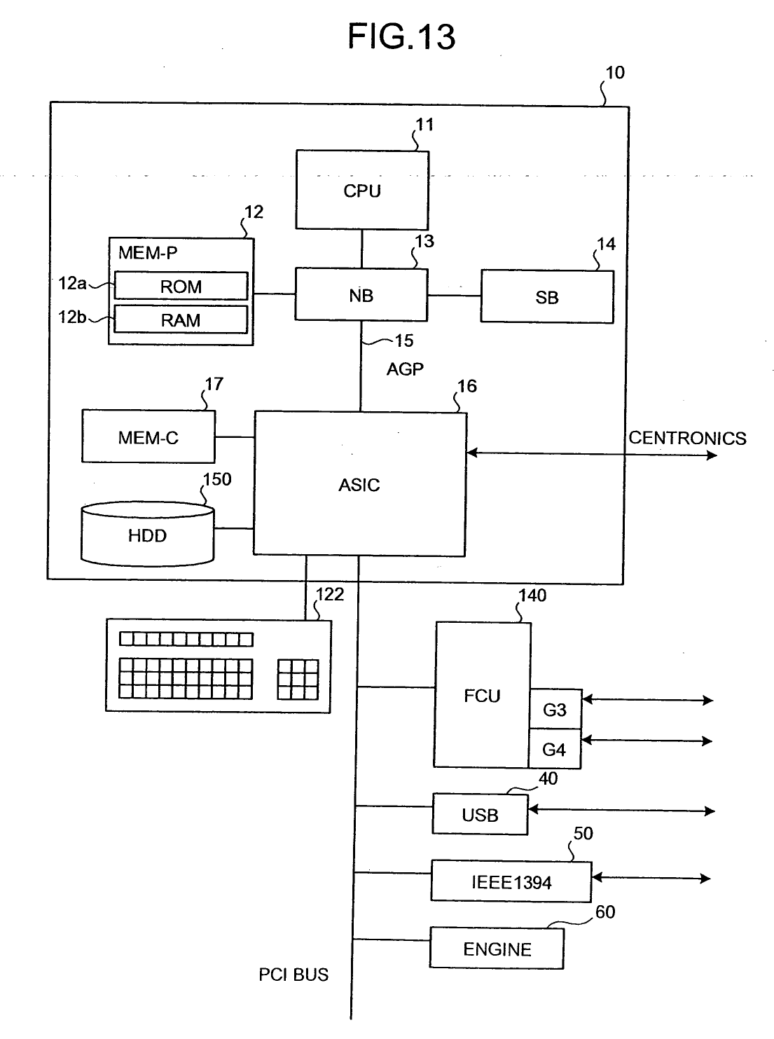

The hardware configuration of the multifunction product 100 is explained below. FIG. 13 is a block diagram of the hardware configuration of the multifunction product 100. As shown in FIG. 13, the multifunction product 100 includes a controller 10 and an engine 60 which are connected by a peripheral component interconnect (PCI) bus.

The controller 10 controls the multifunction product 100, drawing, communication, and input from the operation unit (not shown). The engine 60 is a printer engine or the like connectable to the PCI bus, and is for example, a monochrome plotter, a single-drum color plotter, a four-drum color plotter, a scanner, and a fax unit. The engine 60 includes an image processing unit such as for error diffusion and gamma transformation, in addition to a so-called engine unit such as a plotter. The engine 60 also includes the scanner engine 110 and the printer engine 130 shown in FIG. 1.

The controller 10 includes a central processing unit (CPU) 11, a north bridge (NB) 13, a system memory (MEM-P) 12, a south bridge (SB) 14, a local memory (NEM-C) 17, an application specific integrated circuit (ASIC) 16, and the HDD 150. The NB 13 and the ASIC 16 are connected by an accelerated graphics port (AGP) bus 15. The MEM-P 12 further includes a read only memory (ROM) 12a and a random access memory (RAM) 12b.

The CPU 11 performs overall control of the multifunction product 100, includes a chip set formed of the NB 13, the MEM-P 12, and the SB 14, and is connected to the external apparatus via the chip set.

The NB 13 connects the CPU 11, the MEM-P 12, the SB 14, and the AGP bus 15 with each other, and includes a memory controller that controls read and write with respect to the MEM-P 12, a PCI master, and an AGP target.

The MEM-P 12 is a system memory used as a storage memory for programs and data, a developing memory for the programs and the data, and a drawing memory of the printer, and includes the ROM 12a and the RAM 12b. The ROM 12a is used as the storage memory for the programs and the data, and the RAM 12b is a writable and readable memory to be used as the developing memory for the programs and the data, the drawing memory of the printer, and the like.

The SB 14 connects the NB 13, a PCI device, and a peripheral device with each other. The SB 14 is connected to the NB 13 via the PCI bus, and a network interface (I/F) and the like are also connected to the PCI bus.

The ASIC 16 is an integrated circuit (IC) for application of image processing having a hardware component for the image processing, and functions as a bridge for connecting the AGP bus 15, the PCI bus, the HDD 150, and the MEM-C 17, respectively. The ASIC 16 includes a PCI target, an AGP master, an arbiter (ARB) as a core unit of the ASIC 16, the memory controller that controls the MEM-C 17, a plurality of direct memory access controllers (DMAC) that perform rotation or the like of image data by a hardware logic or the like, and a PCI unit that performs data transfer via the PCI bus between the engine 60 and the ASIC 16. The FCU 140, a universal serial bus (USB) 40, and the Institute of Electrical and Electronics Engineers 1394 (IEEE 1394) interface 50 are connected to the ASIC 16 via the PCI bus.

The MEM-C 17 is used as an image buffer for copying and a code buffer, and the HDD 150 is a storage for storing the image data, programs, font data, and forms.

The AGP bus 15 is a bus interface for a graphics accelerator card proposed for speeding up graphic processing, and improves the speed of a graphics accelerator card by allowing direct access to the MEM-P 12 with high throughput.

The image forming program executed by the multifunction product 100 according to the first embodiment is built in the ROM or the like beforehand.

The image forming program executed by the multifunction product 100 according to the first embodiment can be recorded in an installable format file or an executable format file on a computer readable recording medium such as a CD-ROM, a flexible disk (FD), a CD-R, or a digital versatile disk (DVD).

The image forming program executed by the multifunction product 100 according to the first embodiment can be stored in a computer connected to a network such as the Internet, and downloaded via the network to be provided. Further, the image forming program executed by the multifunction product 100 according to the first embodiment can be provided or distributed via the network such as the Internet.

The image forming program executed by the multifunction product 100 according to the first embodiment has a module configuration including the respective units (scanner engine controller, operation panel controller, printer engine controller, fax communication controller, correction amount detector, correction-amount and image integrating unit, correcting unit, image output controller, and correction-amount correcting unit). As the actual hardware, the CPU (processor) reads the image forming program from the ROM to execute it, so that the respective units are loaded on a main storage device, and generated on the main storage device.

Thus, since the image forming apparatus according to the first embodiment can output the correction amount of the input image and the image data of the input image in association with each other, even when the detected correction amount is wrong, a correction can be performed not based on the corrected image but based on the image data of the input image. Accordingly, the degradation of image quality can be minimized even when the correction is repeated.

An image processing system according to a second embodiment of the present invention detects the inclination angle of the image input by an image processing apparatus, outputs the detected inclination angle and the image data of the input image in association with each other, receives the image data output by the image processing apparatus by an image output apparatus, and corrects the image according to the correction amount, and outputs the image.

In the second embodiment, an example in which the present invention is applied not to a single multifunction product as in the first embodiment, but to the image processing system consisting of the image processing apparatus and the image output apparatus realized by a normal PC or the like is explained.

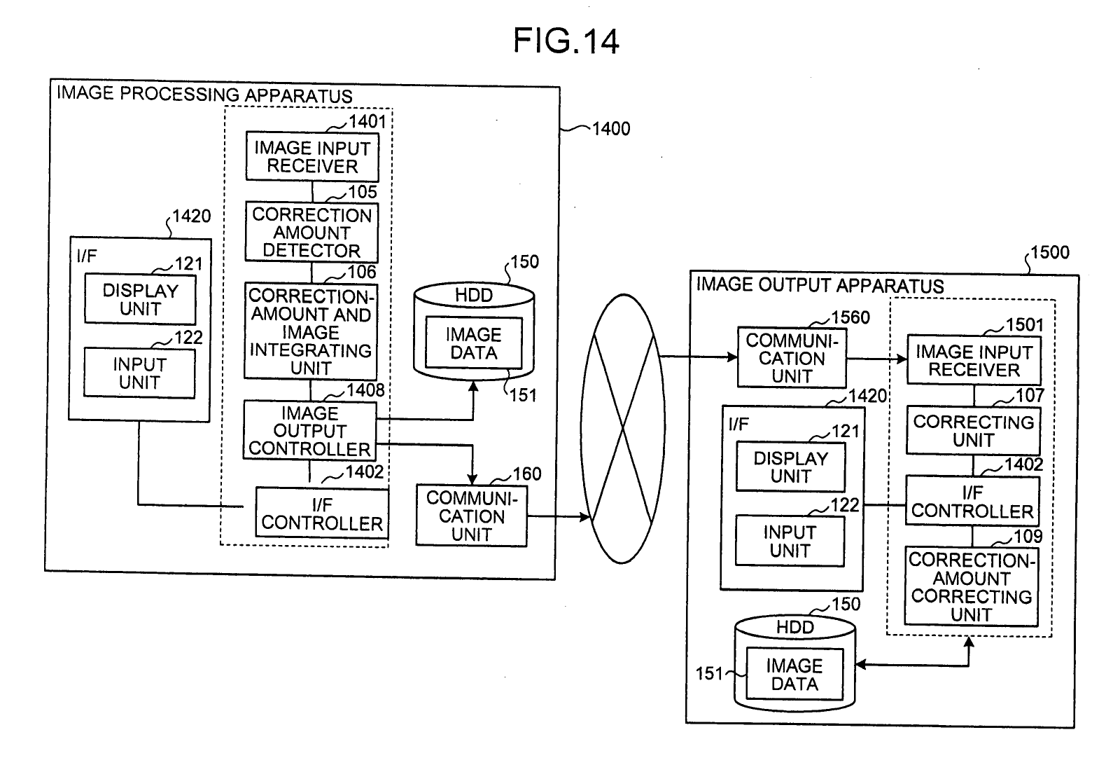

FIG. 14 is a block diagram of the configuration of the image processing system according to the second embodiment. As shown in FIG. 14, in the image processing system, an image processing apparatus 1400 that performs image processing of the input image, and an image output apparatus 1500 that outputs the image are connected with each other via the network such as the Internet.

The network is not limited to the Internet, and the image processing apparatus and the image output apparatus can be connected with each other by any generally used network form. The image processing apparatuses 1400 and image output apparatuses 1500 can be connected.

The image processing apparatus 1400 mainly has the function of creating the intermediate file and outputting the file, of the functions of the multifunction product 100 in the first embodiment. The image output apparatus 1500 mainly has the function of confirming the output image to perform correction of the functions of the multifunction product 100 in the first embodiment.

The image processing apparatus 1400 includes an I/F 1420 as a user interface, the HDD 150, and the communication unit 160, as the major hardware.

The image processing apparatus 1400 includes, as the major software configuration, an image input receiver 1401, an I/F controller 1402, the correction amount detector 105, the correction-amount and image integrating unit 106, and an image output controller 1408. The I/F controller 1402 corresponds to the output controller in the present invention.

The I/F 1420 corresponds to the operation panel 120 of the multifunction product 100 in the first embodiment. The I/F 1420 can be a touch panel type interface functioning as the display unit 121 and the input unit 122 like the operation panel 120, or can be an interface independently including the display unit 121 such as a liquid crystal display (LCD), and the input unit 122 such as a keyboard and a mouse, like an ordinary PC.

Since the functions of the HDD 150 and the communication unit 160 are the same as those in the first embodiment, like reference signs denote like parts, and explanation thereof is omitted.

The image input receiver 1401 receives an input of an image instructed by the user. The input image can be any image. For example, the image can be an image input from the scanner connected to the image processing apparatus 1400, or an image read by an external scanner and stored in the HDD 150.

The I/F controller 1402 controls display of the various screens on the display unit 121 by the I/F 1420, and receives a key input event from the input unit 122. The I/F controller 1402 outputs image data corrected according to the correction amount to the display unit 121.

Since the functions of the correction amount detector 105 and the correction-amount and image integrating unit 106 are the same as those in the first embodiment, like reference signs denote like parts, and explanation thereof is omitted.

The image output controller 1408 controls in order to output the image data output by the correction-amount and image integrating unit 106 to the communication unit 160 for transmitting the image data to the HDD 150 as the built-in storing unit or to the external image output apparatus 1500.

The image output apparatus 1500 includes the I/F 1420 as a user interface, the HDD 150, and a communication unit 1560, as the major hardware.

The image output apparatus 1500 includes an image input receiver 1501, the I/F controller 1402, the correcting unit 107, and the correction-amount correcting unit 109, as the major software configuration.

Since the function of the I/F 1420 is the same as that of the I/F 1420 in the image processing apparatus 1400, and the function of the HDD 150 is the same as that in the first embodiment, like reference signs denote like parts, and explanation thereof is omitted.

The communication unit 1560 receives the image data transmitted from the image processing apparatus 1400 connected thereto via the network. The communication unit 1560 may include the function of transmitting the image data to another image processing apparatus 1400 and image output apparatus 1500.

The image input receiver 1501 receives an input of the image file received by the communication unit 1560.

Since the function of the I/F controller 1402 is the same as that of the I/F controller 1402 in the image processing apparatus 1400, and the functions of the correcting unit 107 and the correction-amount correcting unit 109 are the same as those in the first embodiment, like reference signs denote like parts, and explanation thereof is omitted.

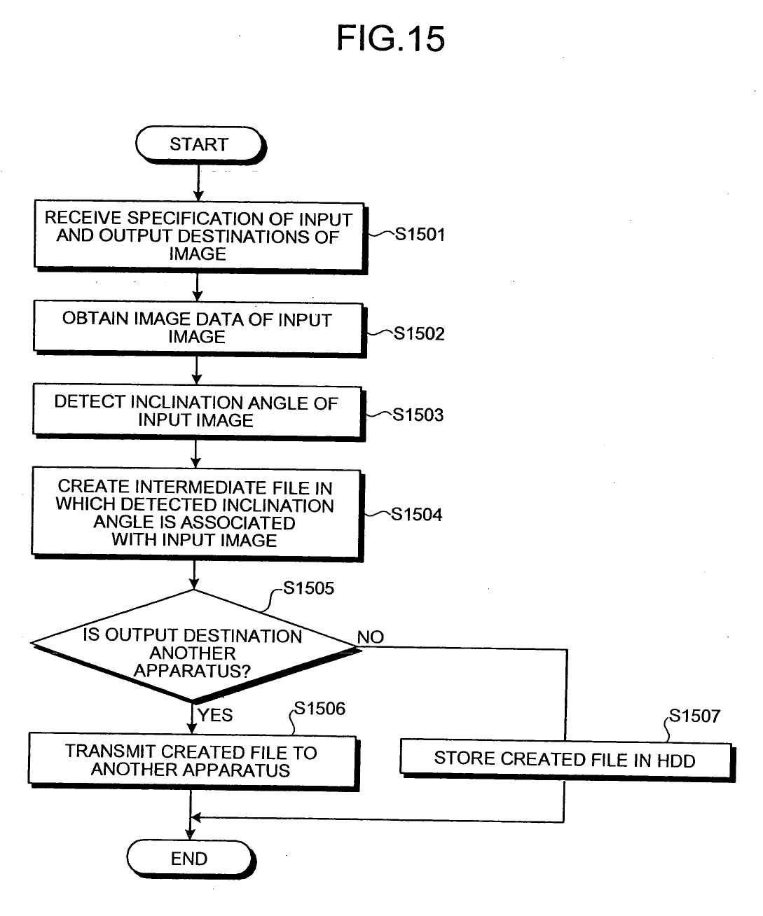

Details of image processing by the image processing apparatus 1400 according to the second embodiment are explained next. FIG. 15 is a flowchart of an overall flow of the image processing in the second embodiment.

The I/F controller 1402 first receives an input operation of an image and an image output destination specified by the user (step S1501). For example, when the user operates an “open file” menu, a screen for selecting an image to be input from a folder storing images in the HDD 150 is displayed on the display unit 121, so that the user can select the image to be input.

When the image is input from a scanner, the input of the image can be started by operating a “scan start” menu and the like.

At the time of specifying an output destination, a screen for selecting storage of image data having been subjected to image processing in the HDD 150, or transmission of the image data to another apparatus is displayed, so that an image output destination can be specified. Output destination-specifying information is stored in a storing unit such as a RAM (not shown). When the image data is output to the HDD 150, a screen for specifying a folder to be output can be displayed. Instead of specifying the output destination first, it may be specified after the image processing.

Upon reception of specification of input and output destinations of the image at step S1501, the image input receiver 1401 receives image data of the specified input image (step S1502).

Since the correction amount detection process and the intermediate file creation process at steps SI 503 and SI 504 are the same as those at steps S402 and S403 performed by the multifunction product 100 according to the first embodiment, explanation thereof is omitted.

The image output controller 1408 determines whether the output destination is another apparatus after execution of the intermediate file creation process (step S1505). At this time, the image output controller 1408 refers to the output destination-specifying information specified at step SI 501 and stored in the storing unit such as the RAM.

When the output destination is another apparatus (step S1505: Yes), the image output controller 1408 transmits the created intermediate file to the other apparatus (step S1506). When the output destination is not another apparatus, the image output controller 1408 stores the created intermediate file in the built-in HDD 150 (step S1507), to finish the image processing.

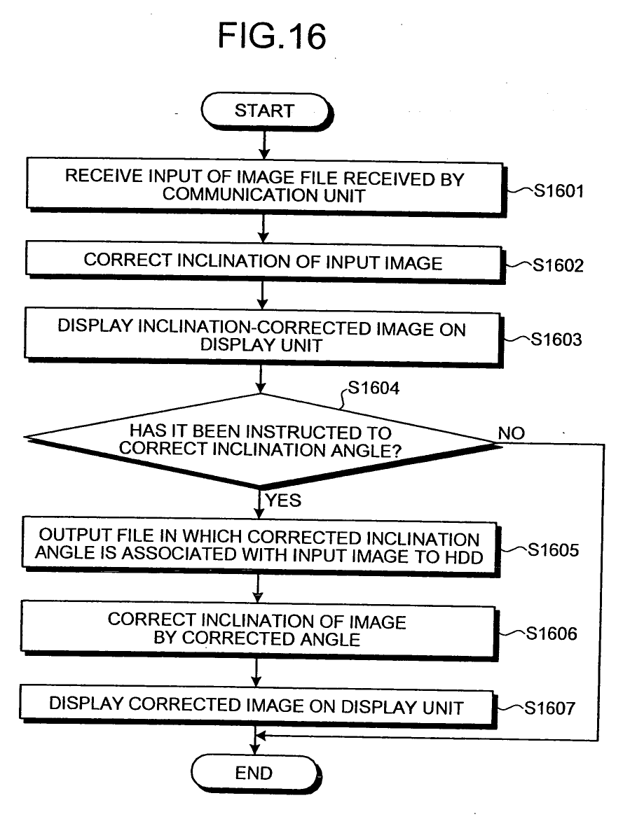

Details of the image output process performed by the image output apparatus 1500 according to the second embodiment are explained below. FIG. 16 is a flowchart of an overall flow of the image output process in the second embodiment.

The image input receiver 1501 in the image output apparatus 1500 receives an input of an image file received by the communication unit 1560 (step S1601).

The correcting unit 107 executes image inclination correction process based on the inclination angle stored in the header of the received image file and the image data in the image file (step S1602).

The I/F controller 1402 displays the inclination-corrected image on the display unit 121 (step S1603), and determines whether the user has instructed inclination angle correction (step S1604).

When the I/F controller 1402 determines that the user has instructed inclination angle correction (step S1604: Yes), the correction-amount correcting unit 109 outputs the image data file, in which the instructed inclination angle is associated with the input image, to the HDD 150 (step S1605).

The correcting unit 107 then executes the image inclination correction process with the corrected inclination angle (step S1606), and re-displays the corrected image on the display unit 121 (step S1607).

After the corrected image is displayed, or when the I/F controller 1402 determines that the user has not instructed inclination angle correction at step S1604 (step S1604: No), the image output process is finished.

Since the image processing system according to the second embodiment includes the image processing apparatus that can output the intermediate file in which the correction amount of the input image is associated with the image data of the input image, even when the detected correction amount is wrong, correction can be performed not based on the corrected image, but based on the image data of the input image.

Since the image processing system includes the image output apparatus that corrects the image data of the input image output in association with the correction amount according to the correction amount and outputs the image data, the user can confirm whether the detected correction amount is wrong on the display unit or the like. Since the image output apparatus can correct the correction amount and perform correction again based on the corrected correction amount and the image data of the input image, the degradation of image quality can be minimized even when the correction is repeated.

An image processing system according to a third embodiment of the present invention receives image data output by the image processing apparatus by a portable terminal, and displays the image corrected according to the correction amount on an LCD screen on the portable terminal.

According to the third embodiment, an example in which the present invention is applied to the image processing system including a device that displays the image formed by a portable terminal such as a mobile phone, instead of the image output apparatus in the second embodiment, is explained.

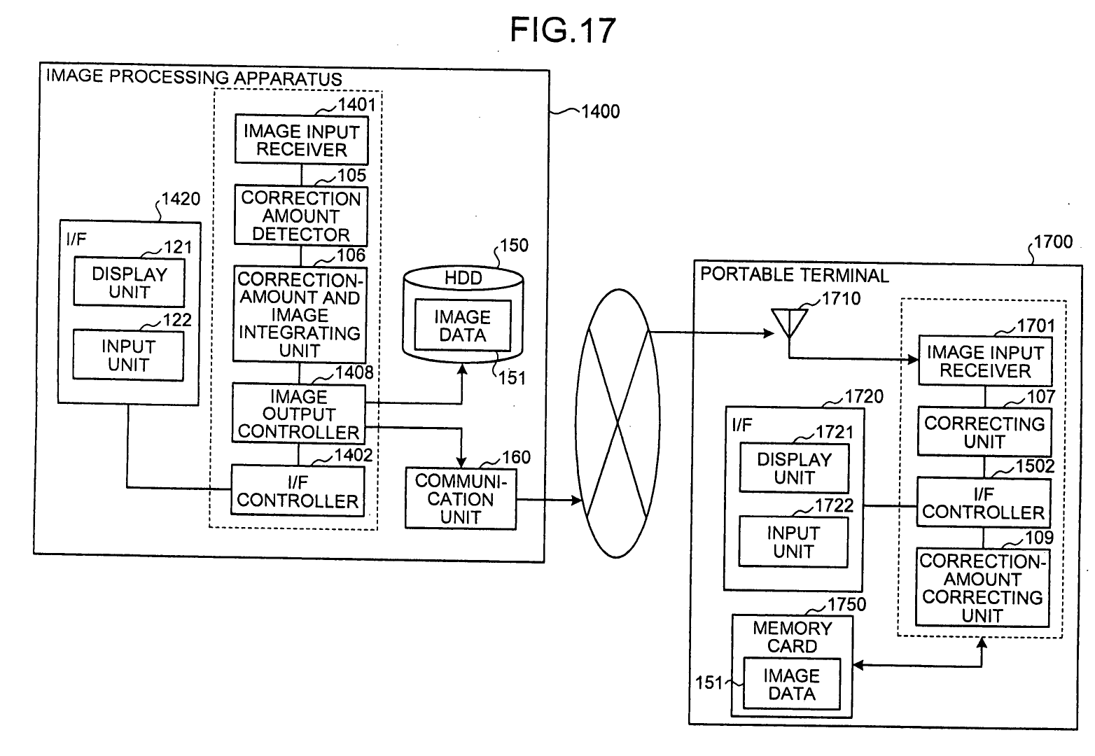

FIG. 17 is a block diagram of the configuration of the image processing system according to the third embodiment. As shown in FIG. 17, in the image processing system, the image processing apparatus 1400 that performs image processing of the input image and a portable terminal 1700 that displays an image are connected by a network such as the Internet.

The network is not limited to the Internet, and image processing apparatus 1400 can be connected to the portable terminal 1700 by any generally used network form. A plurality of image processing apparatuses 1400 and portable terminals 1700 can be connected.

Since the configuration and the function of the image processing apparatus 1400 are the same as those in the second embodiment, like reference signs denote like parts, and explanation thereof is omitted.

The portable terminal 1700 includes an I/F 1720 as a user interface, a memory card 1750, and an antenna 1710 as the major hardware.

The portable terminal 1700 includes an image input receiver 1701, an I/F controller 1502, the correcting unit 107, and the correction-amount correcting unit 109 as the major software configuration. The I/F controller 1502 corresponds to the output controller in the present invention.

The I/F 1720 includes a LCD unit 1721 that displays, for example, a communication history of a mobile phone or a communication instruction screen, or displays an image file or the like in a downloaded PDF format, and an input unit 1722 including buttons for the mobile phone.

The memory card 1750 is a storing unit that stores downloaded image data 151 and the like. The storing unit is not limited to the memory card, and any generally used storing unit that can be loaded into the portable terminal can be used.

The antenna 1710 transfers radio waves including the image data. The image input receiver 1701 obtains the image data from the radio waves received by the antenna 1710.

The I/F controller 1502 controls display of various screens on the LCD unit 1721 by the I/F 1720, and receives a button input event and the like from the input unit 1722. The I/F controller 1502 outputs image data corrected according to the correction amount to the LCD unit 1721.

Since the functions of the correcting unit 107 and the correction-amount correcting unit 109 are the same as those in the first embodiment, like reference signs denote like parts, and explanation thereof is omitted.

The image output process in the image processing system according to the third embodiment is explained. Since the processing by the image processing apparatus 1400 is the same as that in the second embodiment, explanation thereof is omitted.

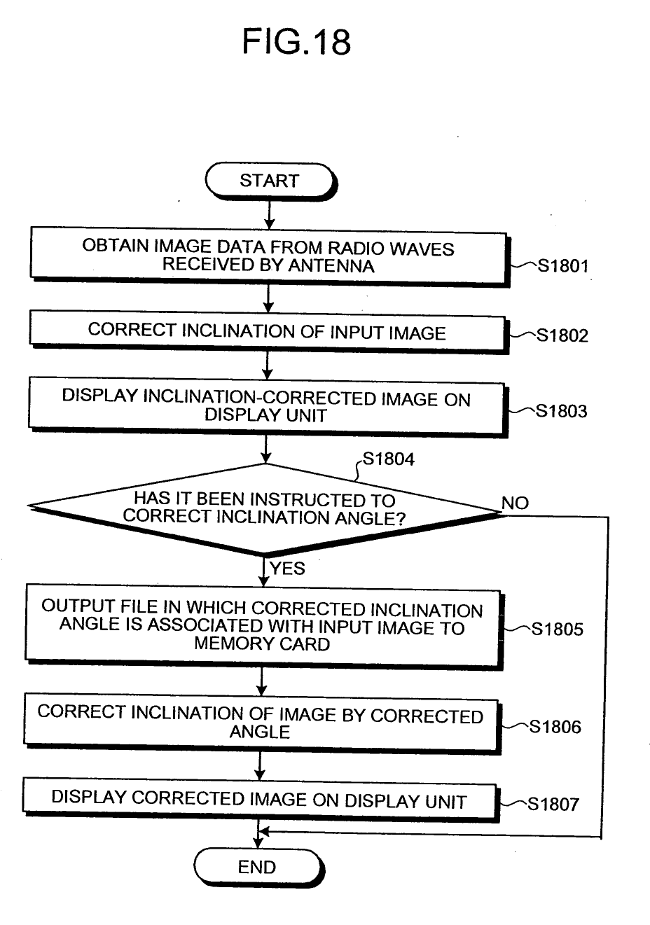

FIG. 18 is a flowchart of an overall flow of the image output process in the third embodiment.

The image input receiver 1701 in the portable terminal 1700 first obtains image data from the radio waves received by the antenna 1710 (step S 1801). The obtained image data is stored in the memory card 1750 as an image file in the same format as the intermediate file including the header created by the image processing apparatus 1400.

Since input image correction process, inclination angle correction process, image file storing process, and image display process at steps S1802 to S1807 are the same as those at steps S1602 to S1607 in the second embodiment, explanations thereof are omitted.

When an image is displayed on the portable terminal 1700 having a small display area such as a mobile phone, the image can be displayed on the LCD unit 1721 after a small image is created by image compression.

When the correcting unit 107 creates an inclination-corrected image, a compressed image corresponding to the display area can be created and output. For example, by calculating a pixel value for every other k pixels (k is an integer) instead of calculating the pixel value for each pixel by affine transformation, an image compressed to 1/k can be created. Accordingly, the processing speed of the image output process can be improved.

In the above example, although the image processing apparatus 1400 is formed of an information processing apparatus such as a PC as in the second embodiment, the image processing apparatus 1400 can also be realized by a portable terminal such as a mobile phone.

For example, when image data of an image photographed by an image pickup device installed in a mobile phone is to be corrected and output, the image data can be output by being associated with the correction amount.

Thus, the image processing system according to the third embodiment can process image data associated with the correction amount by using the portable terminal such as the mobile phone, and display the image on a screen.

According to one embodiment of the present invention, a correction amount of an input image and image data of the input image can be output in association with each other. Accordingly, even when the detected correction amount is wrong, a correction can be performed based on the image data of the input image, not based on the corrected image, thereby minimizing degradation of image quality.

Furthermore, according to one embodiment of the present invention, an inclination angle of an input image can be detected as a correction amount, and the detected inclination angle and the image data of the input image can be output in association with each other. Accordingly, even when the detected inclination angle is wrong, an inclination correction of the image can be performed based on the image data of the input image, not based on the corrected image, thereby minimizing degradation of image quality.

Moreover, according to one embodiment of the present invention, resolution of image data can be detected as a correction amount, and the detected resolution and the input image can be output in association with each other. Accordingly, even when the detected resolution is wrong, a correction of the resolution can be performed based on the input image, not based on the corrected image, thereby minimizing degradation of image quality.

Furthermore, according to one embodiment of the present invention, compression ratio of image data can be detected as a correction amount, and the detected compression ratio and the input image can be output in association with each other. Accordingly, even when the detected compression ratio is wrong, a correction of the compression ratio can be performed based on the input image, not based on the corrected image, thereby minimizing degradation of image quality.

Moreover, according to one embodiment of the present invention, the correction amount can be corrected and output in association with image data. Accordingly, even when the correction amount is erroneously recognized, it can be corrected to an appropriate correction amount, and an image corrected based on the corrected correction amount can be output.

Furthermore, according to one embodiment of the present invention, an image corrected based on the detected correction amount can be output. Therefore, an image can be output, with a problem occurring in the input image being removed.

Moreover, according to one embodiment of the present invention, an image corrected based on the detected correction amount can be displayed on a display unit. Therefore, the user can confirm whether the image is properly corrected, that is, whether the correction amount is not erroneously recognized.

Furthermore, according to one embodiment of the present invention, an image corrected based on the detected correction amount can be printed. Therefore, an image can be printed, with a problem occurring in the input image being dissolved.

Moreover, according to one embodiment of the present invention, an image corrected based on the detected correction amount can be faxed. Therefore, an image can be faxed, with a problem occurring in the input image being removed.

Furthermore, according to one embodiment of the present invention, image data of an input image associated with the detected correction amount can be transmitted to an external image processing apparatus or the like. Therefore, the external image processing apparatus or the like can correct the image based on the input image, not based on the corrected image data, thereby minimizing degradation of image quality due to the correction.

Moreover, according to one embodiment of the present invention, image data of an input image associated with the detected correction amount can be output to a storing unit. Therefore, the image data can be read from the storing unit and used for various purposes such as printing, fax transmission, or transmission to an external apparatus. At this time, image processing such as correction of the image can be performed based on the input image, not based on the corrected image data, thereby minimizing degradation of image quality due to the correction.

Furthermore, according to one embodiment of the present invention, a correction amount of an input image and image data of the input image can be output, in association with each other. Accordingly, even when the detected correction amount is wrong, correction can be performed based on the image data of the input image, not based on the corrected image, thereby minimizing degradation of image quality.

Moreover, according to one embodiment of the present invention, an inclination angle of an input image can be detected as a correction amount, and the detected inclination angle and the image data of the input image can be output in association with each other. Accordingly, even when the detected inclination angle is wrong, inclination correction of the image can be performed based on the image data of the input image, not based on the corrected image, thereby minimizing degradation of image quality.

Furthermore, according to one embodiment of the present invention, resolution of image data can be detected as a correction amount, and the detected resolution and the input image can be output in association with each other. Accordingly, even when the detected resolution is wrong, correction of resolution can be performed based on the input image, not based on the corrected image, thereby minimizing degradation of image quality.

Moreover, according to one embodiment of the present invention, compression ratio of image data can be detected as a correction amount, and the detected compression ratio and the input image can be output in association with each other. Accordingly, even when the detected compression ratio is wrong, correction of compression ratio can be performed based on the input image, not based on the corrected image, thereby minimizing degradation of image quality.

Furthermore, according to one embodiment of the present invention, image data of an input image output in association with the correction amount can be corrected according to the correction amount to be output. Accordingly, an image can be output, with a problem occurring in the input image being removed.

Moreover, according to one embodiment of the present invention, image data of an input image output in association with the correction amount can be corrected according to the correction amount and displayed on a display unit. Therefore, the image with a problem occurring in the input image being dissolved can be confirmed on a display screen.

Furthermore, according to one embodiment of the present invention, the image processing system can be realized, in which the image processing apparatus transmits image data of an input image associated with the correction amount, and the image output apparatus receives the image data, corrects the input image according to the correction amount, and outputs the image. Therefore, even when the detected correction amount is wrong, correction can be performed based on the image data of the input image, not based on the corrected image, thereby minimizing degradation of image quality. Further, an image can be output with a problem occurring in the input image being removed.

Moreover, according to one embodiment of the present invention, the correction amount of an input image and image data of the input image can be output in association with each other. Accordingly, even when the detected correction amount is wrong, correction can be performed based on the image data of the input image, not based on the corrected image, thereby minimizing degradation of image quality.

Furthermore, according to one embodiment of the present invention, the correction amount of an input image and image data of the input image can be output in association with each other. Accordingly, even when the detected correction amount is wrong, correction can be performed based on the image data of the input image, not based on the corrected image, thereby minimizing degradation of image quality.

Moreover, according to one embodiment of the present invention, image data of an input image output in association with the correction amount can be corrected according to the correction amount to be output. Accordingly, an image can be output, with a problem occurring in the input image being removed.

Furthermore, according to one embodiment of the present invention, the methods of the invention can be executed by a computer.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. An image forming apparatus comprising:
a correction-amount detecting unit to detect a correction amount at a time of performing an irreversible correction of an input image; and
a correction-amount and image integrating unit to output the correction amount detected by the correction-amount detecting unit and image data of the input image in association with each other.

2. The image forming apparatus according to claim 1, wherein
the correction-amount detecting unit detects an inclination angle of the input image as the correction amount.

3. The image forming apparatus according to claim 1, wherein
the correction-amount detecting unit detects resolution of the image data as the correction amount.

4. The image forming apparatus according to claim 1, wherein
the correction-amount detecting unit detects a compression ratio of the image data as the correction amount.

5. The image forming apparatus according to claim 1, further comprising:
a correction-amount correcting unit that corrects the correction amount, and outputs the corrected correction amount and the image data in association with each other.

6. The image forming apparatus according to claim 1, further comprising:
a correcting unit to correct the image data based on the correction amount.

7. The image forming apparatus according to claim 6, further comprising:
a display control unit to output the image data corrected by the correcting unit on a display unit.

8. The image forming apparatus according to claim 6, further comprising:
an output control unit to output the image data corrected by the correcting unit to a printer.

9. The image forming apparatus according to claim 6, further comprising:
an output control unit to fax the image data corrected by the correcting unit.

10. The image forming apparatus according to claim 1, further comprising:
an output control unit to transmit the image data associated with the correction amount to an external apparatus.

11. The image forming apparatus according to claim 1, further comprising:
an output control unit to output the image data associated with the correction amount to a storing unit.

12. An image output apparatus comprising:
an image-input receiving unit to receive an input of image data that is output in association with a correction amount at a time of performing an irreversible correction of an input image;
a correcting unit to correct the image data received by the image-input receiving unit based on the correction amount; and
an output controller to output the image data corrected by the correcting unit.

13. An image processing method comprising:
detecting a correction amount when performing an irreversible correction of an input image; and
outputting the detected correction amount and image data of the input image in association with each other.

14. The image processing method according to claim 13, further comprising:
correcting the correction amount; and
outputting the corrected correction amount and the image data in association with each other.

15. The image processing method according to claim 13, further comprising:
correcting the image data based on the correction amount.

16. The image processing method according to claim 13, further comprising:
outputting the corrected image data on a display unit.

17. The image processing method according to claim 13, further comprising:
transmitting the image data associated with the correction amount to an external apparatus.

18. The image processing method according to claim 13, further comprising:
outputting the image data associated with the correction amount to a storing unit.
